(19) United States
(12) Patent Application Publication
(10) Pub. No.: US 2016/0064649 A1
(43) Pub. Date: Mar. 3, 2016

(54) MAGNETIC MEMORY DEVICE

(71) Applicant: KABUSHIKI KAISHA TOSHIBA, Tokyo (JP)

(72) Inventor: Kei WATANABE, Yokkaichi Mie (JP)

(73) Assignee: KABUSHIKI KAISHA TOSHIBA, Tokyo (JP)

(21) Appl. No.: 14/639,689

(22) Filed: Mar. 5, 2015

Related U.S. Application Data
(60) Provisional application No. 62/043,001, filed on Aug. 28, 2014.

(51) Int. Cl. H01L 43/02; H01L 43/08

(52) U.S. Cl. CPC H01L 43/02; H01L 43/08

(57) ABSTRACT

According to one embodiment, a magnetic memory device includes a stack structure including a first magnetic layer, a nonmagnetic layer and a second magnetic layer, a protection insulating film covering at least a side surface of the stack structure, and an intermediate insulating film provided between the stack structure and the protection insulating film, and containing silicon (Si), carbon (C) and hydrogen (H).

### CROSS-REFERENCE TO RELATED APPLICATIONS

This application claims the benefit of U.S. Provisional Application No. 62/043,001, filed Aug. 28, 2014, the entire contents of which are incorporated herein by reference.

### FIELD

Embodiments described herein relate generally to a magnetic memory device.

### BACKGROUND

A magnetic memory device using a magnetoresistive effect element has been proposed. In general, the magnetic memory device has a stack structure including a storage layer, a tunnel barrier layer and a reference layer, and a protection insulating film is provided on a side surface of the stack structure.

However, in such a conventional magnetic memory device as described above, there is a risk that characteristics of the magnetic memory device will be deteriorated due to a stress acting on the stack structure.

### BRIEF DESCRIPTION OF THE DRAWINGS

FIG. 1 is a cross-sectional view schematically showing a structure of a magnetic memory device according to an embodiment;

FIG. 2 is a view showing coefficient ratios of thermal expansion and moduli of elasticity of various materials;

FIG. 3 is a cross-sectional view schematically showing a structure of a magnetic memory device according to a modification of the embodiment; and

FIG. 4 is a view schematically showing a general structure of a semiconductor integrated circuit device in which a magnetoresistive effect element (MTJ element) is employed.

### DETAILED DESCRIPTION

In general, according to one embodiment, a magnetic memory device includes a stack structure including a first magnetic layer, a nonmagnetic layer and a second magnetic layer; a protection insulating film covering at least a side surface of the stack structure; and an intermediate insulating film provided between the stack structure and the protection insulating film, and containing silicon (Si), carbon (C) and hydrogen (H).

Embodiments will be described with reference to the accompanying drawings.

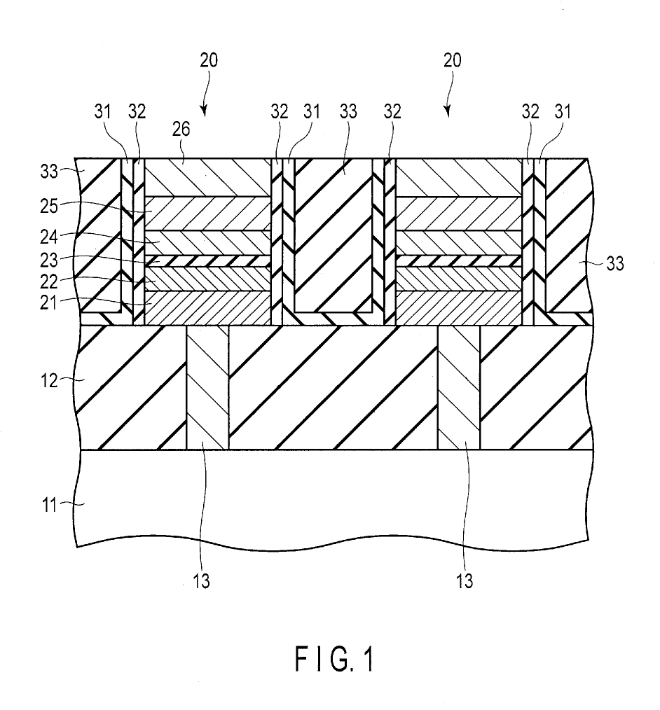

FIG. 1 is a cross-sectional view schematically showing a structure of a magnetic memory device according to an embodiment.

As shown in FIG. 1, an interlayer insulating film 12 is formed on a semiconductor substrate 11, and a contact plug 13 is formed in the interlayer insulating film 12. It should be noted that transistors (not shown) such as a selection transistor are formed in a surface region of the semiconductor substrate 11.

On the interlayer insulating film 12, a stack structure 20 including a magnetic layer functioning as a magnetic storage layer is formed. The stack structure 20 forms a magnetoresistive effect element. It should be noted that the magnetoresistive effect element is also referred to as a magnetic tunnel junction (MTJ) element.

The stack structure 20 comprises a under layer 21, a storage layer 22, a tunnel barrier layer 23, a reference layer 24, a shift canceling layer 25 and a cap layer 26.

The storage layer 22 is a magnetic layer (first magnetic layer) having variable magnetization. The reference layer 24 is a magnetic layer (second magnetic layer) having fixed magnetization. The tunnel barrier layer 23 is an insulating nonmagnetic layer provided between the storage layer 22 and the reference layer 24. The shift canceling layer 25 is intended to apply to the storage layer 22, a magnetic field acting in a direction opposite to a direction in which a magnetic field is applied from the reference layer 24 to the storage layer 22.

An MTJ element having the above stack structure 20 is a magnetic element having perpendicular magnetization. That is, a magnetization direction of the storage layer 22, the reference layer 24 and the shift canceling layer 25 is perpendicular to surfaces of those layers. If the magnetization direction of the storage layer 22 and that of the reference layer 24 are parallel to each other, the MTJ element exhibits a low resistance state. If the magnetization direction of the storage layer 22 and that of the reference layer 24 are antiparallel, the MTJ element exhibits a high resistance state. It is possible to store binary information (0 or 1) in accordance with whether the MTJ element is in the low resistance state or the high resistance state. It is also possible to write binary information (0 or 1) in accordance with a flowing direction of current in the MTJ element.

The storage layer 22, the reference layer 24 and the shift canceling layer 25 are formed of materials having negative magnetostriction coefficients. The materials having negative magnetostriction coefficients each include at least one of iron (Fe), cobalt (Co) and nickel (Ni).

The storage layer 22 can be formed of an alloy including at least one of iron (Fe), cobalt (Co) and nickel (Ni) and at least one of chromium (Cr), platinum (Pt), palladium (Pd), iridium (Ir), rhodium (Rh), ruthenium (Ru), osmium (Os), rhenium (Re) and gold (Au). Also, it can be formed of a perpendicular magnetization film of artificial lattice in which those alloys are stacked together. For example, it can be formed of a stacked film comprising a nonmagnetic substance and a magnetic substance, e.g., Co/Pt, Co/Pd or Co/Ru. Furthermore, the storage layer 22 can be formed by combing Ru and PtMn, IrMn or the like, which is an antiferromagnetic substance. In addition, it may be formed of, e.g., CoFeB which is an alloy.

The reference layer 24 can be formed of an L1₀ ordered alloy such as FePd or FePt. Furthermore, an element such as Cu may be added to the ordered alloy to adjust an anisotropic magnetic energy density or a saturation magnetization of the ordered alloy. Also, the shift canceling layer 25 can be formed of the same materials as the reference layer 24.

The tunnel barrier layer 23 can be formed of an insulating film such as MgO, CaO, SrO, TiO, VO, NbO or Al₂O₃. Also, it is preferable that the tunnel barrier layer 23 be formed of an oxide having a NaCl structure.

The cap layer 26 can be formed of metal such as ruthenium (Ru) or tantalum (Ta).

At least a side surface of the stack structure 20 is covered by a protection insulating film 31. It is preferable that the protection insulating film 31 be formed of insulating material having a tensile stress. It is also preferable that the protection insulating film 31 be formed of material restricting transmission of gas or moisture.

For example, the protection insulating film 31 can be formed of material containing silicon (Si) and nitrogen (N). Also, the protection insulating film 31 may contain oxygen (O) in addition to silicon (Si) and nitrogen (N). To be more specific, the protection insulating film 31 can be formed of a silicon nitride film (SiN film) or a silicon oxynitride film (SiON film). For example, it can be formed of a silicon nitride film having a tensile stress greater than several tens of megapascals and formed by plasma CVD. Also, it can be formed of a silicon nitride film formed by nitriding a polysilicon film. Furthermore, at least between elements, a buried insulating film 33 is buried in such a way as to cover the protection insulating film 31. The buried insulating film 33 can be formed of material containing silicon (Si) and oxygen (O). It can be formed of, e.g., a silicon oxide film formed by plasma CVD or coating.

Between the stack structure 20 and the protection insulating film 31, an intermediate insulating film 32 is formed. The intermediate insulating film 32 functions as a buffer film between the stack structure 20 and the protection insulating film 31 and the buried insulating film 33, and can reduce a stress acting on the stack structure 20.

It is preferable that a coefficient of thermal expansion of the intermediate insulating film (buffer film) 32 be close to that of the stack structure 20. To be more specific, it is preferable that the coefficient of thermal expansion of the intermediate insulating film 32 be greater than 0.5 times that of the stack structure 20 and smaller than 5 times that of the stack structure 20. After the intermediate insulating film 32 is formed at a high temperature (e.g., approximately 300° C.), when the temperature is decreased, a thermal stress generates due to a difference between the coefficient of thermal expansion of the intermediate insulating film 32 and that of the stack structure 20. If the coefficient of thermal expansion of the intermediate insulating film 32 is close to that of the stack structure 20, it is possible to reduce the stress between the intermediate insulating film 32 and the stack structure 20. Furthermore, it is preferable that the intermediate insulating film (buffer film) 32 have a low modulus of elasticity. By applying an intermediate insulating film 32 having a low modulus of elasticity, even if a protection insulating film 31 (e.g., a silicon nitride film) having a high modulus of elasticity and a buried insulating film 33 having a high modulus of elasticity are applied, it is possible to reduce a stress which acts on the stack structure 20 due to the protection insulating film 31 and the buried insulating film 33.

The above intermediate insulating film (buffer film) 32 is selected from a first intermediate insulating film, a second intermediate insulating film and a third intermediate insulating film, which will be described as follows:

The first intermediate insulating film contains silicon (Si), carbon (C) and hydrogen (H). It is preferable that a carbon concentration of the first intermediate insulating film be equal to or greater than 30 atomic %. For example, the first intermediate insulating film can be formed of silicon carbide (SiC) containing hydrogen. Furthermore, the first intermediate insulating film may contain an alkyl group such as a methyl group.

The second intermediate insulating film contains carbon (C), hydrogen (H) and nitrogen (N). The second intermediate insulating film may further contain a small amount of oxygen (O). Also, it is preferable that the carbon concentration of the second intermediate insulating film be 50 atomic % or more. For example, the second intermediate insulating film can be formed of an organic insulating material such as polyimide.

The third intermediate insulating film is formed of an aromatic compound. For example, the third intermediate insulating film can be formed of an aromatic hydrocarbon polymer. To be more specific, the third intermediate insulating film can be formed of SiLK (registered trademark).

It should be noted that the intermediate insulating film 32 can be formed by chemical vapor deposition (CVD), atomic layer deposition (ALD), vapor deposition, coating, or the like.

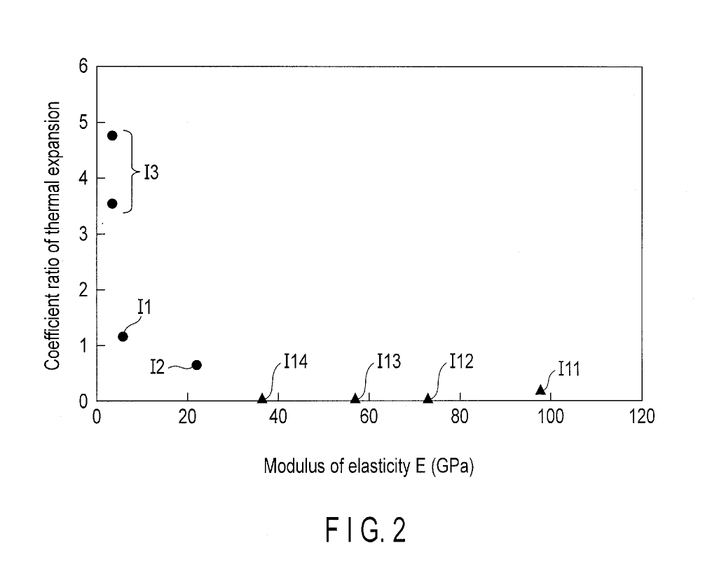

FIG. 2 is a view showing coefficient ratios of thermal expansion and moduli of elasticity (Young's moduli) of various materials. The coefficient ratios of thermal expansion are ratios of the coefficients of thermal expansion of the various materials (the intermediate insulating film 32, etc.) to that of the stack structure 20.

In FIG. 2, I1 indicates material of the first intermediate insulating film. To be more specific, it is silicon carbide (SiC) containing hydrogen. 12 indicates material of the second intermediate insulating film. To be more specific, it is polyimide. 13 indicates material of the third intermediate insulating film. To be more specific, it is an aromatic hydrocarbon polymer. Also, FIG. 2 shows another insulating material as a comparative example. I11, I12, I13 and I14 indicate a silicon nitride, a silicon oxide, a silicon oxynitride, and a silicon oxide to which fluorine is added, respectively.

As shown in FIG. 2, the coefficients of thermal expansion of the first to third intermediate insulating films, one of which is applied as the intermediate insulating film 32, are greater than 0.5 times that of the stack structure 20 and smaller than 5 times that of the stack structure 20. On the other hand, the coefficient of thermal expansion of the material of the comparative example is much less than that of the stack structure 20. It is therefore preferable that the coefficients of thermal expansion of the first to third intermediate insulating films be greater than 0.5 times that of the stack structure 20 and smaller than 5 times that of the stack structure 20. The moduli of elasticity of the first to third intermediate insulating films are smaller than 30 (GPa), whereas those of materials of the comparative example are greater than 30 (GPa).

As described above, in the embodiment, between the stack structure 20 and the protection insulating film 31, the intermediate insulating film 32 is provided which is selected from among the first to third intermediate insulating films. The intermediate insulating film 32 functions as a buffer film between the stack structure 20 and the protection insulating film 31, and can reduce the stress acting on the stack structure 20.

Furthermore, since the intermediate insulating film 32 is selected from the first to third intermediate insulating films, it can be interposed between the stack structure 20 and the protection insulating film 31 as an intermediate insulating film having a coefficient of thermal expansion close to that of the stack structure 20. It is therefore possible to reduce the stress acting on the stack structure 20.

In addition, the intermediate insulating film 32 selected from the first to third intermediate insulating films has a low modulus of elasticity. Therefore, even if a protection insulating film 31 having a high modulus of elasticity is applied, it is also possible to reduce a stress which acts on the stack structure 20 due to the protection insulating film 31.

As described above, by virtue of provision of the intermediate insulating film 32, it is possible to reduce the stress acting on the stack structure 20, and also restrict deterioration of a magnetic characteristic which is caused by an inverse magnetostriction effect. Therefore, according to the embodiment, a superior magnetic memory device can be obtained.

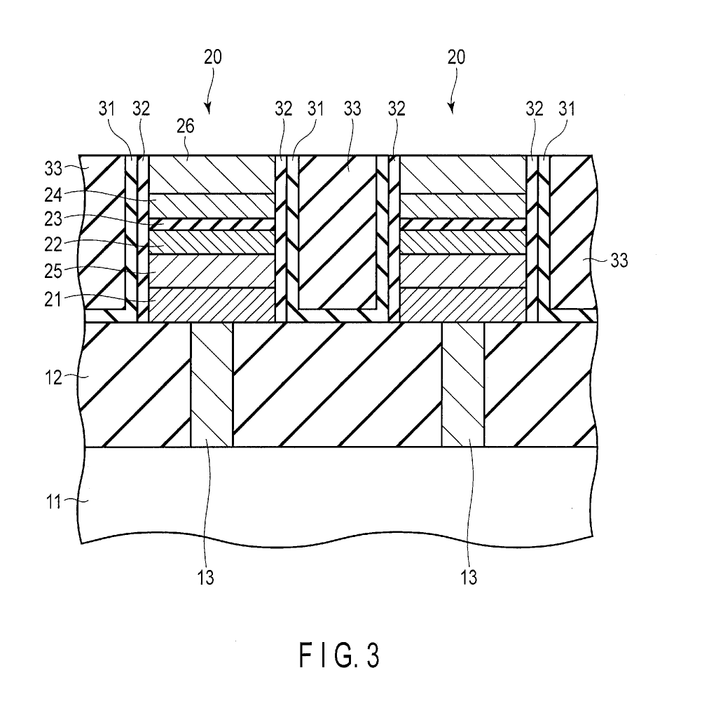

It should be noted that in the above embodiment, as shown in FIG. 1, the shift canceling layer 25 is provided on an upper layer side with respect to the storage layer 22; however, as shown in FIG. 3, the shift canceling layer 25 may be provided on a lower layer side with respect to the storage layer 22. Such a structure can also obtain the same advantage as in the above embodiment.

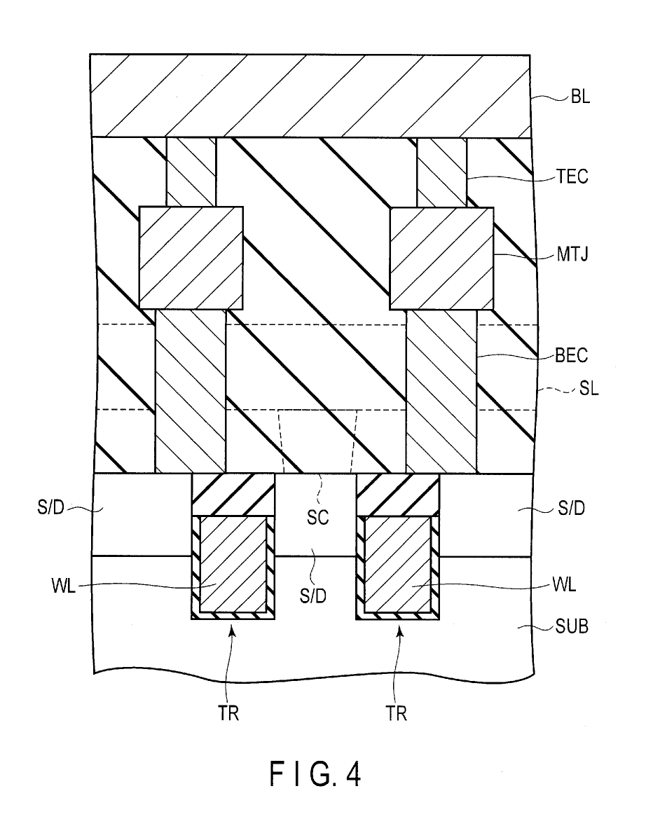

FIG. 4 is a view schematically showing a general structure of a semiconductor integrated circuit device in which a magnetoresistive effect element (MTJ element) is employed.

A buried gate type MOS transistor TR is formed in a semiconductor substrate SUB. A gate electrode of the MOS transistor TR is used as a word line WL. A bottom electrode BEC is connected to one of source/drain regions S/D of the MOS transistor TR, and a source line contact SC is connected to the other of the source/drain regions S/D.

A magnetoresistive effect element MTJ is formed on the bottom electrode BEC, and a top electrode TEC is formed on the magnetoresistive effect element MTJ. A bit line BL is connected to the top electrode TEC. A source line SL is connected to the source line contact SC.

An excellent semiconductor integrated circuit device can be obtained by applying the structure and the method described in the above embodiment to the semiconductor integrated circuit device shown in FIG. 4.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising:
a stack structure including a first magnetic layer, a nonmagnetic layer and a second magnetic layer;
a protection insulating film covering at least a side surface of the stack structure; and
an intermediate insulating film provided between the stack structure and the protection insulating film, and containing silicon (Si), carbon (C) and hydrogen (H).

2. The device of claim 1, wherein a coefficient of thermal expansion of the intermediate insulating film is greater than 0.5 times that of the stack structure and smaller than 5 times that of the stack structure.

3. The device of claim 1, wherein a carbon concentration of the intermediate insulating film is equal to or greater than 30 atomic %.

4. The device of claim 1, wherein the intermediate insulating film is silicon carbide containing hydrogen.

5. The device of claim 1, wherein the protection insulating film contains silicon (Si) and nitrogen (N).

6. The device of claim 1, wherein the first magnetic layer has variable magnetization, and the second magnetic layer has fixed magnetization.

7. A magnetic memory device comprising:
a stack structure including a first magnetic layer, a nonmagnetic layer and a second magnetic layer;
a protection insulating film covering at least a side surface of the stack structure; and
an intermediate insulating film provided between the stack structure and the protection insulating film and containing carbon (C), hydrogen (H) and nitrogen (N).

8. The device of claim 7, wherein the intermediate insulating film further contains oxygen (O).

9. The device of claim 7, wherein a coefficient of thermal expansion of the intermediate insulating film is greater than 0.5 times that of the stack structure and smaller than 5 times that of the stack structure.

10. The device of claim 7, wherein a carbon concentration of the intermediate insulating film is equal to or greater than 50 atomic %.

11. The device of claim 7, wherein the intermediate insulating film is polyimide.

12. The device of claim 7, wherein the protection insulating film contains silicon (Si) and nitrogen (N).

13. The device of claim 7, wherein the first magnetic layer has variable magnetization, and the second magnetic layer has fixed magnetization.

14. A magnetic memory device comprising:
a stack structure including a first magnetic layer, a nonmagnetic layer and a second magnetic layer;
a protection insulating film covering at least a side surface of the stack structure; and
an intermediate insulating film provided between the stack structure and the protection insulating film, and formed of an aromatic compound.

15. The device of claim 14, wherein a coefficient of thermal expansion of the intermediate insulating film is greater than 0.5 times that of the stack structure and smaller than 5 times that of the stack structure.

16. The device of claim 14, wherein the intermediate insulating film is an aromatic hydrocarbon polymer.

17. The device of claim 14, wherein the protection insulating film contains silicon (Si) and nitrogen (N).

18. The device of claim 14, wherein the first magnetic layer has variable magnetization, and the second magnetic layer has fixed magnetization.
